(19) United States
(12) Patent Application Publication
(10) Pub. No.: US 2021/0242154 A1
(43) Pub. Date: Aug. 5, 2021

(54) INTERCONNECT STRUCTURES AND ASSOCIATED SYSTEMS AND METHODS

(71) Applicant: Micron Technology, Inc., Boise, ID (US)

(72) Inventor: Kyle K. Kirby, Eagle, ID (US)

(21) Appl. No.: 16/781,603

(22) Filed: Feb. 4, 2020

(51) Int. Cl. H01L 23/00

(52) U.S. Cl. CPC H01L 24/13; H01L 24/16; H01L 24/81; H01L 2224/13564; H01L 2224/81815; H01L 2224/13082; H01L 2224/13019; H01L 2224/16148; H01L 2224/1357

(57) ABSTRACT

An interconnect structure for a semiconductor device is provided herein. The interconnect structure generally includes a conductive pillar electrically coupled to a conductive contact positioned on a semiconductor die and a trace receiver on a distal end of the pillar. The trace receiver has a body electrically coupled to the distal end, and may include a first leg projecting from a first side of the body away from the distal end and a second leg projecting from a second side of the body away from the distal end, such that the body, the first leg, and the second leg together form a cavity. During assembly of the semiconductor device, the cavity is configured to at least partially surround a portion of a semiconductor trace positioned in an insulated substrate. To form the electrical connection, a solder material may be disposed between the trace receiver and the trace.

### TECHNICAL FIELD

The present disclosure is generally directed to semiconductor devices, and in several embodiments, more particularly to interconnect structures for die-to-substrate and/or three-dimensional integration interconnects.

### BACKGROUND

Microelectronic devices, such as memory devices, microprocessors, and light emitting diodes, typically include one or more semiconductor dies mounted to a substrate and encased in a protective covering. The semiconductor dies include functional features, such as memory cells, processor circuits, interconnecting circuitry, etc. Semiconductor die manufacturers are under increasing pressure to reduce the volume occupied by semiconductor dies while increasing the capacity and/or speed of the resulting encapsulated assemblies. To meet these demands, semiconductor die manufacturers often stack multiple semiconductor dies vertically on top of each other to increase the capacity or performance of a microelectronic device within the limited volume on the circuit board or other element to which the semiconductor dies are mounted. For vertically stacked semiconductor dies, through-silicon vias (TSV) are often used. Such TSVs on adjacent semiconductor dies are typically electrically connected to each other using direct physical coupling in which the bond pads of one die are directly bonded to the bond pads of the other.

Individual or stacked semiconductor dies are typically electrically connected through metal bond pads on the dies, or by pillars formed on the bond pads. When the dies are electrically connected to a substrate, the pads or pillars typically form a connection to exposed traces in the substrate using solder bumps attached to the metal pads or pillars. During assembly, the solder bumps are reflowed to form the connection from die-to-substrate (D2S). Conventional assembly methods typically result in a solder connection confined to the tip of the metal pillar and the top side of the trace in the substrate. Often, the bond pads of each semiconductor die are spaced closely together such that when solder is reflowed during the stacking process to form the solder bumps, the solder can form an electrical “bridge” between adjacent metal pillars to electrically connect adjacent pillars and short the semiconductor device.

### BRIEF DESCRIPTION OF THE DRAWINGS

FIG. 1A is an enlarged cross-sectional view showing a semiconductor device having interconnect structures including trace receivers configured in accordance with an embodiment of the present technology before forming an electrical connection through interconnects.

FIG. 1B is an enlarged cross-sectional view showing the semiconductor device of FIG. 1A after forming the electrical connection through the interconnects.

FIGS. 2A-2D are cross-sectional detail views of interconnect structures having various trace receivers configured in accordance with embodiments of the present technology.

FIG. 3 is a perspective view showing a semiconductor device having an interconnect structure including a trace receiver configured in accordance with an embodiment of the present technology before forming an electrical connection through an interconnect.

FIG. 4 is a schematic view of a system that includes a semiconductor device configured in accordance with embodiments of the present technology.

### DETAILED DESCRIPTION

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device.

Depending upon the context in which it is used, the term “substrate” can refer to a structure that supports electronic components (e.g., a die), such as a wafer-level substrate, a singulated die-level substrate, or another die for die-stacking applications. A person having ordinary skill in the relevant art will recognize that suitable steps of the methods described herein can be performed at the wafer-level or at the die level. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, spin coating, plating, and/or other suitable techniques. Similarly, materials can be removed, for example, using plasma etching, wet etching, chemical-mechanical planarization, or other suitable techniques.

In several embodiments, a semiconductor die includes at least one contact (e.g., bond pads or portions of TSVs that extend through the die) exposed at a surface. In these embodiments, an interconnect structure is electrically coupled to the contact for forming electrical connections with other components of the semiconductor device. In some embodiments, the interconnect structure includes conductive metal pillars on the bond pads of the die that are configured to electrically couple to traces exposed in the substrate (e.g., another die in a die-stacking application, a printed circuit board, a die-level or wafer-level substrate, etc.). As noted above, such connections are typically referred to as D2S connections.

In some conventional interconnect structures, pillars are formed on bond pads of a die. The pillars are electrically coupled to traces in a substrate by reflowing or reforming solder material at the tip of the pillar. The solder material contacts a surface on the pillars and a surface on the traces to form an electrical connection. In these configurations, the limited surface area of the pillars and traces that interfaces the solder material causes a relatively weak structural connection. D2S interconnect methods are vulnerable to a variety of reliability issues during assembly, including misalignment, solder bridging, solder slumping, incomplete wetting, die warpage, edge or corner connections, coefficient of thermal expansion mismatch, and low mechanical strength, among others. As array configurations increase in density, the bond pads of each die can have a greater pitch, which increases the tendency of encountering the above difficulties.

In some embodiments described herein, an additional conductive structure is formed at an end of the pillar opposite the die. The additional structure includes a trace receiver configured for retention of the solder material. As will be described in greater detail below, such trace receivers are formed with one or more voids or cavities having at least one opening, and in several embodiments the void or cavity has a shape complementary to the shape of the traces in the substrate (e.g., the cavity of the trace receiver generally corresponds to the size, shape, pitch, depth, etc., of the surfaces of the trace). For example, the receivers can be a generally elongate bar with three substantially rectilinear sides exposed in the substrate such that the cavity has a C-shaped opening facing away from the pillar toward the trace. In these embodiments, the size and shape of the cavity in the trace receiver may be configured to allow a solder material gap between the trace receiver and the trace when the die is placed in an assembled position relative to the substrate. In other embodiments, the shape of the void or cavity is any shape suitable to interface the traces in the substrate (e.g., a curved interior surface).

Among other advantages over conventional technology, the trace receiver configuration described herein (a) aids in alignment of the pillars with the traces, (b) provides greater mechanical stability, (c) can withstand multiple reflows of the solder material when assembling multi-die stacks, (d)n can accommodate a higher degree of die warpage, (e) reduces solder bridging, (f) allows tighter pitch interconnect and substrate designs, (g) assists in non-conductive film processing (NCF), and (h) allows for tighter bond line control. The configurations of the present technology may be described herein in reference to TSV and/or three-dimensional integration (3DI); however, the present technology also applies to other interconnect types, including flip chip bonding (FC), direct chip attachment (DCA), and D2S, among others. The description of the present technology in conjunction with a specific configuration should not be construed as limiting the applications of the present technology.

The description and illustration of the shapes of the trace receivers and traces herein are exemplary, and should not be construed as limiting the scope of the present disclosure. In this regard, in several embodiments, the shape of the traces in the substrate is any shape created by suitable manufacturing processes to expose conductive material enabling an electrical connection, and such a shape may vary between substrates, traces on the same substrate, and/or adjacent traces. Likewise, in other embodiments, the shape of the cavity in the trace receiver is any suitable shape configured to enable an electrical connection with the traces, and may not necessarily be shaped complementarily to the shape of the traces (e.g., an arcuate cavity in the trace receiver is compatible with a substantially rectilinear trace, etc.). In these embodiments, the trace receiver is sized and shaped to electrically connect to the trace and form a bond having an increased mechanical strength compared to conventional technology. Further, the cavity in the trace receiver is configured to substantially confine the solder material to the cavity such that solder to solder shorting and electrical bridging is prevented.

As used herein, the terms “vertical,” “lateral,” “upper,” and “lower” can refer to relative directions or positions of features in the semiconductor devices in view of the orientation shown in the Figures. For example, “upper” or “uppermost” can refer to a feature positioned closer to the top of a page than another feature. These terms, however, should be construed to include semiconductor devices having other orientations, such as inverted or inclined orientations where top/bottom, over/under, above/below, up/down, left/right, and distal/proximate can be interchanged depending on the orientation. Moreover, for ease of reference, identical reference numbers are used to identify similar or analogous components or features throughout this disclosure, but the use of the same reference number does not imply that the features should be construed to be identical. Indeed, in many examples described herein, identically numbered features have a plurality of embodiments that are distinct in structure and/or function from each other. Furthermore, the same shading may be used to indicate materials in cross section that can be compositionally similar, but the use of the same shading does not imply that the materials should be construed to be identical unless specifically noted herein.

The present disclosure may also reference quantities and numbers. Unless specifically stated, such quantities and numbers are not to be considered restrictive, but exemplary of the possible quantities or numbers associated with the new technology. Also, in this regard, the present disclosure may use the term “plurality” to reference a quantity or number. In this regard, the term “plurality” is meant to be any number that is more than one, for example, two, three, four, five, etc. For the purposes of the present disclosure, the phrase “at least one of A, B, and C,” for example, means (A), (B), (C), (A and B), (A and C), (B and C), or (A, B, and C), including all further possible permutations when greater than three elements are listed.

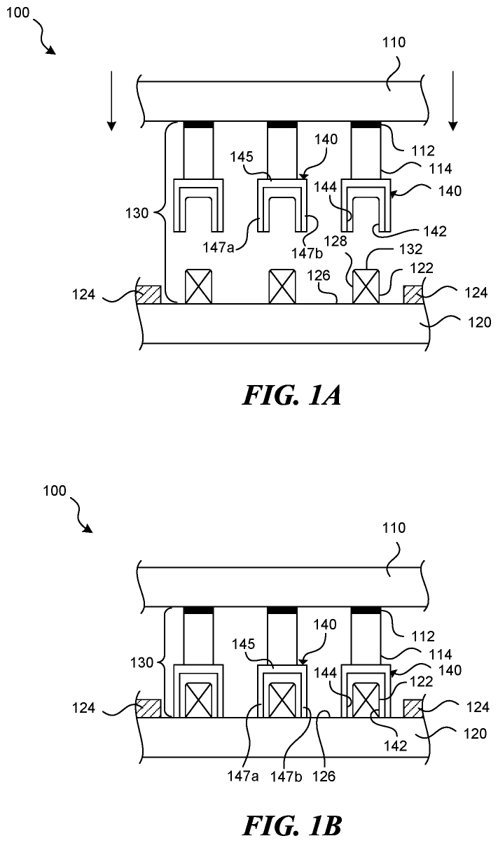

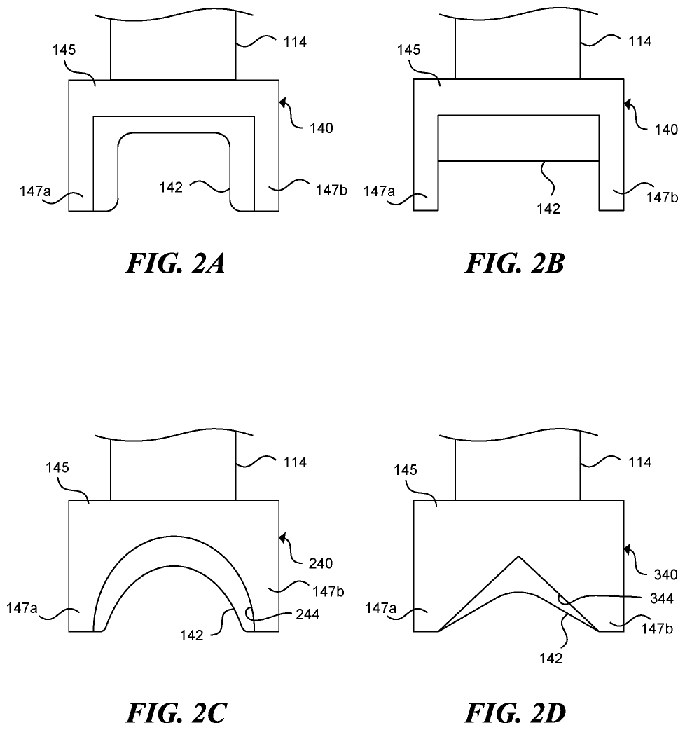

FIGS. 1A and 1B show a cross-sectional view of a semiconductor device 100 in accordance with an embodiment of the present technology. FIG. 1A shows the semiconductor device 100 in a position before electrically connecting the components, and FIG. 2B shows the semiconductor device 100 after electrically connecting the components. The semiconductor device 100 (e.g., a semiconductor die assembly) generally includes a substrate 120 and a semiconductor die 110 electrically couplable to the substrate 120 by an interconnect assembly 130. As described herein, the semiconductor die 110 can be an individual die having one or more integrated circuits, or the semiconductor die 110 can be a stack of multiple, electrically connected semiconductor dies.

In some embodiments of the present technology, the substrate 120 includes a dielectric material 124, (e.g., a passivation material, a polyimide material, solder resist/mask, and/or other materials used to cover a top surface of a semiconductor device) and conductive traces 122 having peripheral surfaces 128 and a distal surface 132. The insulating material 124 at least partially covers a surface of the substrate 120 and is locally removed to form an open area 126 to at least partially expose the conductive traces 122. The insulating material 124 may be removed to a depth that exposes the peripheral surfaces 128 of the traces 122.

The semiconductor die 110 generally includes a plurality of electrically conductive contacts 112 exposed at a surface of the semiconductor die 110 that are electrically coupled to an integrated circuit of the semiconductor die 110 and are configured to be electrically coupled to another semiconductor die of a die stack or a another type of substrate (e.g., a printed circuit board). In some embodiments, the contacts 112 are bond pads, while in other embodiments, the contacts 112 can be a portion of a via (e.g., a TSV) that extends partially or completely through the semiconductor die 110. The integrated circuitry of the semiconductor die 110 can include a memory circuit (e.g., a dynamic random memory (DRAM)), a controller circuit (e.g., a DRAM controller), a logic circuit, and/or other circuits or combinations of circuits.

In some embodiments, the interconnect assembly 130 includes conductive (e.g., metal) pillars 114 projecting from the contacts 112 on the semiconductor die 110 and extending in a direction generally perpendicular to the semiconductor die 110. However, in other embodiments, the pillars 114 extend at an angle between 85° and 90° from the semiconductor die 110. In further embodiments, pillars 114 extend at an angle between 88° and 90° from the semiconductor die 110. The pillars 114 may have a length configured to provide desired spacing between the semiconductor die 110 and the substrate 120 when the semiconductor device 100 is assembled.

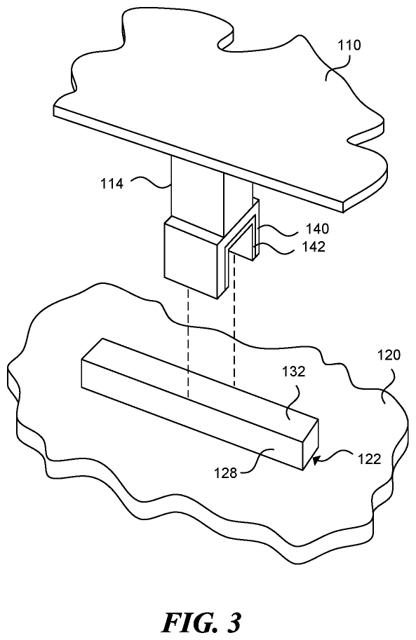

In conventional semiconductor devices, the pillar is generally electrically connected to the traces using an exposed solder material (e.g., the solder material is not retained by any structure). In contrast, embodiments of the present technology include trace receivers 140 at the ends of the pillars 114 that are configured to retain a quantity of a solder material 142. The trace receivers 140 may have a length in a direction corresponding to a longitudinal axis of the trace 122 that is smaller than the length of the exposed trace 122 in the substrate 120 (see, e.g., FIG. 3). In these embodiments, individual trace receivers 140 create an electrical connection with only a portion of the exposed trace 122. The trace receivers 140 may have a length in a direction corresponding to a longitudinal axis of the trace 122 that is substantially the same size or longer than the exposed length of the trace 122.

As shown in FIGS. 1A and 1B, an individual trace receiver 140 may have a body 145, a first leg 147a projecting away from one side of the body 145, and a second leg 147b projecting away from the other side of the body 145 to create a cavity 144 configured to retain the solder material 142. In several embodiments, the cavity 144 has a shape generally complementary to the shape of a corresponding trace 122 of the substrate 120. The trace receivers 140 may be formed on a corresponding pillar 114 with the cavity 144 having three substantially rectilinear interior surfaces (see, e.g., FIGS. 2A and 2B), which correspond to the size, shape, pitch, depth, etc. of the surfaces of the trace 122. For example, the cavity 144 of a trace receiver can have a “C-shape” with the opening of the cavity 144 facing away from the pillar 114 toward the trace 122.

The cavity 144 of individual trace receivers 140 may be at least partially filled with the solder material 142 to form the electrical connection with the traces 122 upon assembly of the semiconductor device 100. The solder material 142 may conform to the shape of the cavity 144 to generally correspond to the shape of the trace 122 (e.g., FIG. 2A), or the solder material 142 may fill the cavity 144 in other configurations, such as a flat configuration (e.g., FIG. 2B). In general, the size and shape of the cavity 144 in the trace receiver 140 may be configured to allow a gap in the solder material 142 between the trace receiver 140 and the trace 122 when the semiconductor die 110 is placed in an assembled position relative to the substrate 120. In these embodiments, the volume of the solder material 142, and the size and shape of the cavity 144, are specified such that solder runoff is minimized to prevent solder shorting. Additionally, the gap in which the solder material 142 flows between the trace receiver 140 and the trace 122 may be configured with tolerances specified to still allow an electrical connection to form between the trace receiver 140 and the trace 122 when the semiconductor die 110 is warped, adjacent pillars 114 are of differing lengths, etc. In the assembled position, the distal-most ends of the trace receivers 140 may contact a surface of the substrate 120 (FIG. 1B) to further inhibit solder bridging.

FIGS. 2C and 2D show embodiments of trace receivers with different shaped cavities. FIG. 2C, more specifically, shows a trace receiver 240 having an arcuate cavity 244 configured to retain the solder material 142. In this embodiment, the arcuate cavity 244 may not match the shape of a substantially rectilinear trace 122, but such an arcuate cavity 244 is compatible with a variety of trace shapes within the scope of the present technology. FIG. 2D shows a trace receiver 340 having an angular cavity 344, which may be compatible with a variety of trace shapes within the scope of the present technology. The trace receivers 140, 240, and 340 may contact the trace 122 at certain points in the assembled position as the solder material 142 fills gaps and creates the electrical connection. In other embodiments, the shape of the cavity in each trace receiver is formed as a result of one or more of manufacturing capability, manufacturing process, cost, reliability, bond strength, trace shape, substrate variance, preference of the designer, etc.

The components of the interconnect assembly 130 are generally formed from conductive materials, such as copper, nickel, gold, etc., and combinations thereof. In some embodiments, the pillar 114 and the trace receiver 140 may be formed using any suitable patterning method, such as using subtractive processing with a photomask to form a pit in which the trace receiver 140 can be plated.

FIG. 3 shows a trace receiver 140 being coupled to a trace 122. During assembly of the semiconductor device 100, the semiconductor die 110 is positioned such that the trace receiver 140 is aligned with the trace 122 to receive a portion of the trace 122 within the cavity 144. In some embodiments, the solder material 142 within the cavity 144 is preheated to allow solder flow prior to the trace receiver 140 of the semiconductor die 110 being brought into proximity to the trace 122. The semiconductor device 100 may have a substantially uniform gap between the trace receiver 140 and the trace 122 when assembled. The cavity 144 may be only partially filled with solder material 142 with a preformed shape such that the solder material 142 surrounds at least a portion of a distal surface 132 and at least a portion of a peripheral surface 128 of the trace 122 prior to solder reflow. In other embodiments, the solder material 142 is not preheated, but is positioned in contact with one or more surfaces of the trace 122 such that the solder material 142 can be heated with other interconnect assemblies 130 during a gang reflow. The configuration of the trace receiver 140 and the trace 122 allows for multiple reflows of the solder material 142 that reduces the risk of solder bridging. In embodiments where the solder material 142 is not preheated, a gang reflow may be performed using sonic energy, whereby friction between the materials creates heat to reflow the solder material 142.

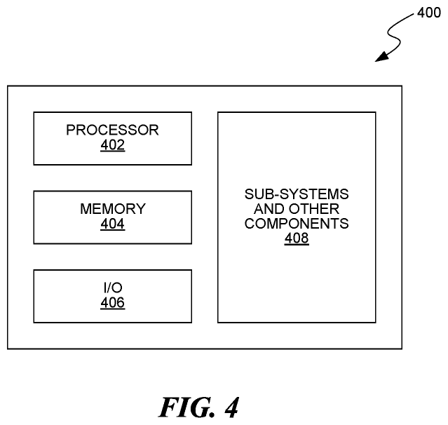

FIG. 4 is a block diagram illustrating a system that incorporates a semiconductor device in accordance with embodiments of the present technology. Any one of the semiconductor devices having the features described above with reference to FIGS. 1A-43 can be incorporated into any of a myriad of larger and/or more complex systems, a representative example of which is system 400 shown schematically in FIG. 4. The system 400 can include a processor 402, a memory 404 (e.g., SRAM, DRAM, flash, and/or other memory devices), input/output devices 406, and/or other subsystems or components 408. The semiconductor assemblies, devices, and device packages described above with reference to FIGS. 1A-3 can be included in any of the elements shown in FIG. 5. The resulting system 400 can be configured to perform any of a wide variety of suitable computing, processing, storage, sensing, imaging, and/or other functions. Accordingly, representative examples of the system 400 include, without limitation, computers and/or other data processors, such as desktop computers, laptop computers, Internet appliances, hand-held devices (e.g., palm-top computers, wearable computers, cellular or mobile phones, personal digital assistants, music players, etc.), tablets, multi-processor systems, processor-based or programmable consumer electronics, network computers, and minicomputers. Additional representative examples of the system 400 include lights, cameras, vehicles, etc. In these and other examples, the system 400 can be housed in a single unit or distributed over multiple interconnected units, e.g., through a communication network. The components of the system 400 can accordingly include local and/or remote memory storage devices and any of a wide variety of suitable computer-readable media.

From the foregoing, it will be appreciated that specific embodiments of the new technology have been described herein for purposes of illustration, but that various modifications may be made without deviating from the present disclosure. Accordingly, the invention is not limited except as by the appended claims. Furthermore, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the present disclosure. Accordingly, the present disclosure and associated technology can encompass other embodiments not expressly shown or described herein.

I/We claim:

1. An interconnect structure for a semiconductor device, the interconnect structure comprising:
a conductive pillar electrically coupled to a conductive contact positioned on a semiconductor die, the conductive pillar having a distal end opposite the conductive contact; and
a trace receiver having:
a body electrically coupled to the distal end of the pillar;
a first leg projecting from a first side of the body away from the distal end; and
a second leg projecting from a second side of the body away from the distal end, wherein the body, the first leg, and the second leg together form a cavity configured to receive a portion of a semiconductor trace therein.

2. The interconnect structure of claim 1, wherein the first leg and the second leg extend at least partially along peripheral surfaces of the semiconductor trace when the semiconductor device is in an assembled position.

3. The interconnect structure of claim 1, further comprising a solder material disposed in at least a portion of the cavity.

4. The interconnect structure of claim 3, wherein the solder material contacts a distal surface of the semiconductor trace and at least one peripheral surface along a side of the semiconductor trace in an assembled position.

5. The interconnect structure of claim 3, wherein the trace receiver is configured to form a gap between the trace receiver and the semiconductor trace in an assembled position such that when the solder material is heated during assembly of the semiconductor device, the solder material within the trace receiver flows to at least partially surround exposed surfaces of the semiconductor trace.

6. The interconnect structure of claim 1, wherein the first and second legs form plates that project perpendicularly away from the body such that the cavity has three rectilinear inner surfaces.

7. The interconnect structure of claim 1, wherein the first and second legs taper away from the body such that the cavity has an arcuate inner surface.

8. The interconnect structure of claim 1, wherein the first and second legs taper away from the body such that the cavity has two inner surfaces having an angle therebetween.

9. The interconnect structure of claim 1, wherein the semiconductor trace is positioned on a semiconductor substrate having an insulating material.

10. The interconnect structure of claim 9, wherein the semiconductor trace is exposed by an opening in the insulating material.

11. A semiconductor assembly, comprising:
a substrate having a trace exposed at a surface of the substrate;
a semiconductor die having a conductive contact; and
an interconnect structure electrically coupling the trace and the conductive contact, the interconnect structure having:
a conductive pillar electrically coupled to the conductive contact; and
a trace receiver having a body electrically coupled to a distal end of the pillar opposite the conductive contact, a first leg projecting from a first side of the body away from the distal end, and a second leg projecting from a second side of the body away from the distal end, wherein the body, the first leg, and the second leg together form a cavity configured to receive a portion of the trace therein.

12. The semiconductor assembly of claim 11, wherein the first leg and the second leg of the trace receiver extend at least partially along peripheral surfaces of the trace.

13. The semiconductor assembly of claim 11, wherein the trace receiver is electrically coupled to the trace with a solder material disposed between the trace receiver and the trace.

14. The semiconductor assembly of claim 13, wherein the solder material contacts a distal surface of the trace and at least one peripheral surface along a side of the trace.

15. The semiconductor assembly of claim 11, wherein the first and second legs form plates that project perpendicularly away from the body such that the cavity has three rectilinear inner surfaces.

16. The semiconductor assembly of claim 11, wherein the first and second legs taper away from the body such that the cavity has an arcuate inner surface.

17. The semiconductor assembly of claim 11, wherein the first and second legs taper away from the body such that the cavity has two inner surfaces having an angle therebetween.

18. The semiconductor assembly of claim 11, wherein the trace is exposed by an opening in an insulating material on the substrate.

19. A semiconductor assembly, comprising:
a substrate having a first trace and a second trace exposed at a surface of the substrate;
a semiconductor die having a first conductive contact and a second conductive contact;
a first interconnect structure electrically coupling the first trace and the first conductive contact; and
a second interconnect structure electrically coupling the second trace and the second conductive contact,
wherein each of the first and second interconnect structures have:
a conductive pillar electrically coupled to a corresponding conductive contact; and
a trace receiver having a body electrically coupled to a distal end of the pillar opposite the conductive contact, a first leg projecting from a first side of the body away from the distal end, and a second leg projecting from a second side of the body away from the distal end, wherein the body, the first leg, and the second leg together form a cavity configured to receive a portion of a corresponding trace therein,
wherein the first leg of the first interconnect structure is positioned between opposing peripheral surfaces of the first and second traces such that a solder material disposed in the trace receiver of the first interconnect structure cannot form an electrical bridge to the second trace.

20. The semiconductor assembly of claim 19, wherein the second leg of the second interconnect structure is positioned between the first leg of the first interconnect structure and the peripheral surface of the second trace.

21. The semiconductor assembly of claim 19, wherein the first leg and the second leg of the first interconnect structure extend at least partially along peripheral surfaces of the first trace.

22. The semiconductor assembly of claim 19, wherein:
the first interconnect structure is electrically coupled to the first trace by a solder material disposed between the trace receiver of the first interconnect structure and the first trace, and
the second interconnect structure is electrically coupled to the second trace by the solder material disposed between the trace receiver of the second interconnect structure and the second trace.

23. The semiconductor assembly of claim 22, wherein the solder material contacts distal surfaces of the first and second traces and at least one peripheral surface along a side of each of the first and second traces.

24. The semiconductor assembly of claim 19, wherein the first and second legs of each of the first and second interconnect structures form plates that project perpendicularly away from the body such that the cavities of the first and second interconnect structures have three rectilinear inner surfaces.

25. The semiconductor assembly of claim 19, wherein the first and second legs of each of the first and second interconnect structures taper away from the body such that the cavities of the first and second interconnect structures have an arcuate inner surface.

26. The semiconductor assembly of claim 19, wherein the first and second legs of each of the first and second interconnect structures taper away from the body such that the cavities of the first and second interconnect structures have two inner surfaces having angles therebetween.

27. The semiconductor assembly of claim 19, wherein the first and second traces are exposed by an opening in an insulating material on the substrate.
